(19) United States
(12) Patent Application Publication
(10) Pub. No.: US 2025/0130279 A1
(43) Pub. Date: Apr. 24, 2025

(54) POWER VECTOR ANALYZER

(71) Applicant: Tektronix, Inc., Beaverton, OR (US)

(72) Inventor: John J. Pickerd, Hillsboro, OR (US)

(21) Appl. No.: 18/914,685

(22) Filed: Oct. 14, 2024

Related U.S. Application Data
(60) Provisional application No. 63/592,060, filed on Oct. 20, 2023.

(51) Int. Cl. G01R 31/319; G01R 27/28; G01R 35/00

(52) U.S. Cl. CPC G01R 31/31924; G01R 27/28; G01R 35/007

(57) ABSTRACT

A power vector analyzer to analyze power from a device under test (DUT) includes one or more channels to measure a reference voltage signal from a power line connected to the DUT, one or more channels to measure a reference current signal from the power line, a user interface comprising a display and one or more controls, and a quadrature synchronous detector (QSD) for each phase of apparent power being measured, the QSD configured to use a reference voltage signal from the one or more channels and a reference current signal from the one or more channels to determine the apparent power for each phase of power being measured by the DUT and display the apparent power for each phase on the display.

### CROSS-REFERENCE TO RELATED APPLICATIONS

This disclosure is a non-provisional of and claims benefit from U.S. Provisional Application No. 63/592,060, titled “ELECTRIC MOTOR VECTOR ANALYZER,” filed on Oct. 20, 2023, the disclosure of which is incorporated herein by reference in its entirety.

### TECHNICAL FIELD

The present disclosure relates to power vector analyzers, more particularly to power vector analyzers using synchronous complex detectors using a complex null vector to calibrate to a reference operating point of a motor.

### BACKGROUND

The global electric vehicle (EV) motor market was worth USD 8.5 billion in 2022 and is predicted to be worth around USD 65.95 billion by 2032, expanding growth at compound annual growth rate of 21% from 2023 to 2032 according to Precedence Research. Therefore, there is a need to facilitate this growth through improved technology.

The electric vehicle (EV) marketplace is growing rapidly as governments are working to phase out gasoline-powered vehicles and replace them with electric vehicles. Each EV typically has one or two three-phase electric motors, which can be on the order of 500 HP combined. For example, one Tesla motor operates at 200 kW with variable three-phase, pulse width modulated sine wave power supplied by a DC to AC inverter. The frequency of the inverter may vary in the range of 20 Hz to 300 Hz. Motor drive voltage is variable on the order of 750 Vₚₚ and the current may be on the order of 27 Aₚₚ.

The capability to analyze a power signal, such as those in electric motors, to determine phase and magnitude of the power signal relative to a reference signal is useful. U.S. Pat. No. 6,525,522, “System for Determining the Phase and Magnitude of an Incident Signal Relative to a Cyclical Reference Signal,” which is incorporated by reference herein in its entirety, describes an example of one system with that capability.

There are examples of motor analysis tools in the market. One such example of prior art for motor analysis is the Fluke Model 438-2 quality motor analyzer. Some examples of three-phase power analyzers that can display power on a vector plot include the Fluke 437 II Power Quality and Energy Analyzer, the Hioki PW6001 Power Analyzer, and the Yokogawa WT3000E Precision Power Analyzer.

### BRIEF DESCRIPTION OF THE DRAWINGS

FIG. 1 shows an embodiment of a user interface on a power vector analyzer (PVA) displaying quiescent power for three-phase power.

FIG. 2 shows an embodiment of a user interface on a PVA during nulling of quiescent power.

FIG. 3 shows an embodiment of a user interface on a power vector analyzer displaying nulled quiescent power.

FIG. 4 shows an embodiment of a user interface on a power vector analyzer displaying measured power transients relative to a nulled quiescent power.

FIG. 5 shows an embodiment of display showing measured power transients including a limit circle relative to nulled quiescent power.

FIG. 6 shows embodiments of a user interface on a power vector analyzer showing different possible probe configurations.

FIG. 7 shows an embodiment of a power vector analyzer having a single-phase motor with a load and a quadrature synchronous detector (QSD) for one-phase power.

FIG. 8 shows a representative of the power vector relationships.

FIG. 9 shows an example of a block diagram of using three QSDs for three phase power.

FIG. 10 shows an embodiment of a QSD generating a null vector.

FIG. 11 shows a more focused flow chart of a QSD.

FIG. 12 shows a block diagram of a rotation block.

FIG. 13 shows an embodiment of a scale block diagram.

FIG. 14 shows an embodiment of a power vector analyzer architecture.

### DETAILED DESCRIPTION

The embodiments herein involve a power vector analyzer (PVA) for analyzing power signals under load, such as in electric motors or even from the power grid. The PVA of the embodiments may provide additional capabilities to an existing motor or power analyzers. The embodiments here provide improved user interfaces and a transparent null vector calculation. The null vector determination used in the embodiments provides a complex power measurement that the PVA can display as a trace of real-time variations in the complex load impedance of motors or other power consumption systems, represented as power vectors. The ability to analyze start up characteristics of power signals, and the behavior of the power consuming entities such as motors or large equipment, as examples, has value.

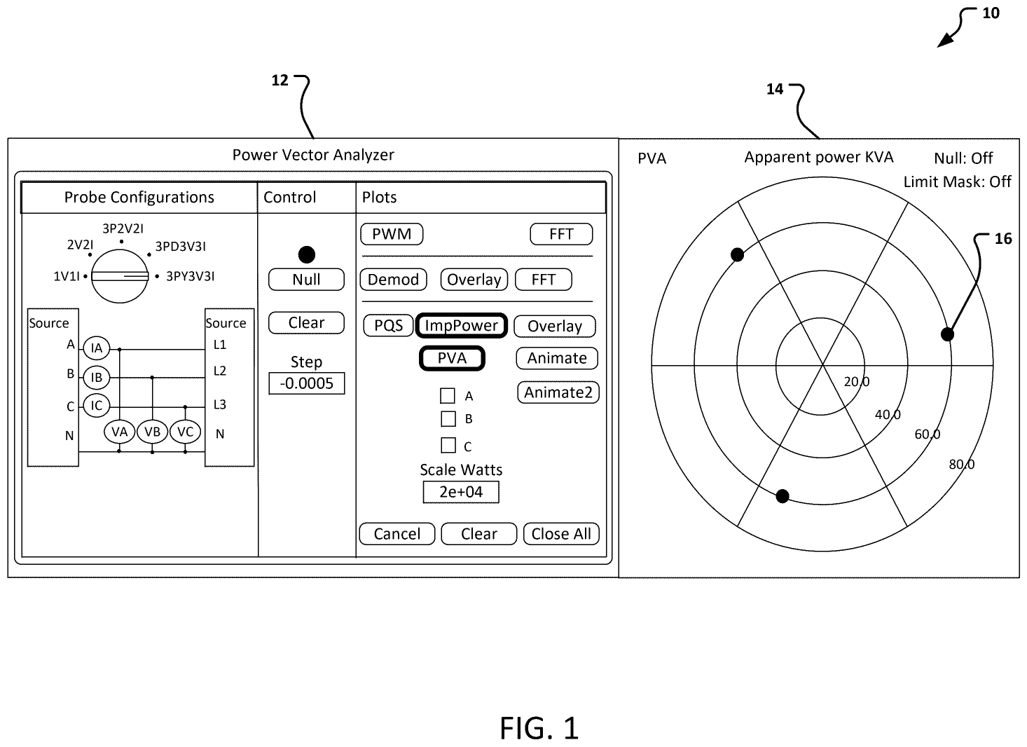

The PVA of the embodiments can display the quiescent power signals before any operation of a device under test, such as a motor or other power devices. FIG. 1 shows a user interface 10 having controls 12 on the left side and a display 14 on the right. The dots such as 16 represent the “reference” apparent power signal for each of three phases on a polar grid, each phase being 120° out of phase with the other two phases. The controls 12 allow the user to set probe configurations, start, and stop the null process, clear a previously determined nulled quiescent power, and make selections about the plots. The term “reference apparent power” applies to the apparent power being displayed before removal of the quiescent power to differentiate them from the apparent power being measured after the null process.

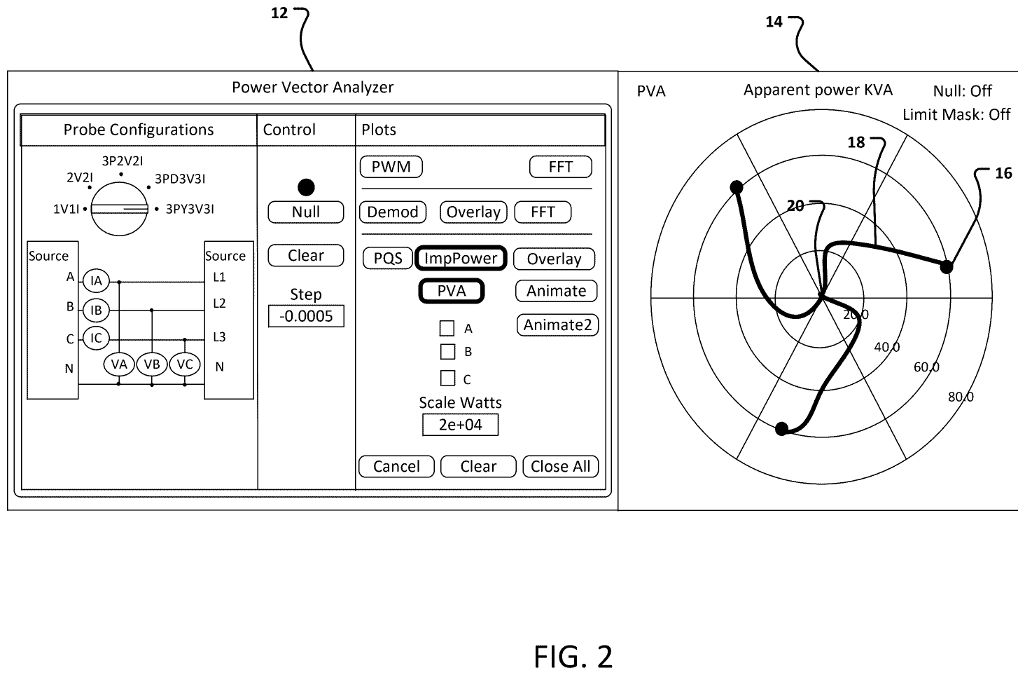

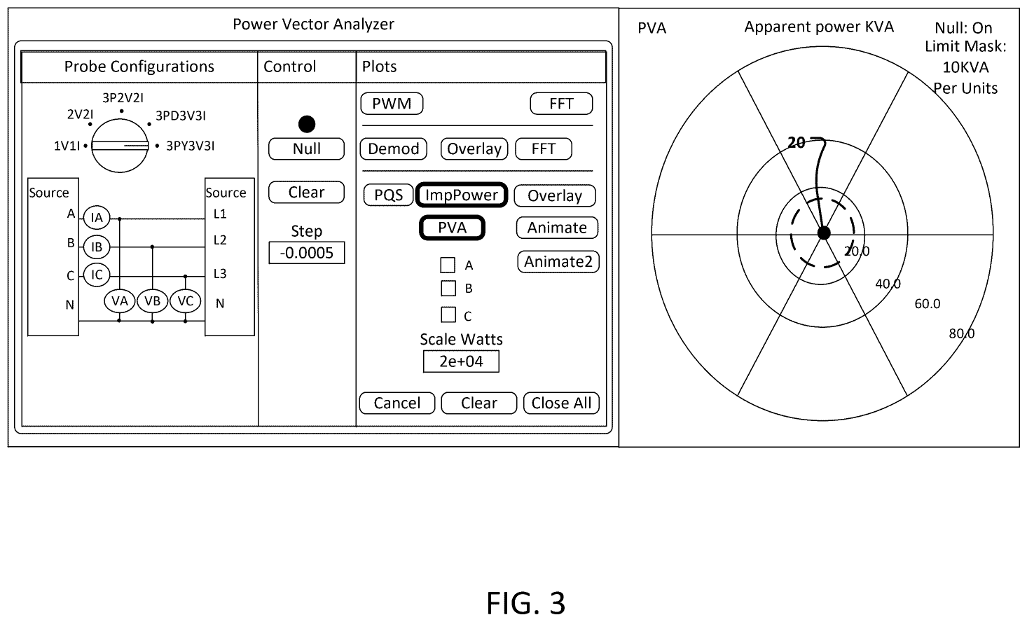

FIG. 2 shows an embodiment of the user interface during the null calculation process that will be discussed in detail below. The null process essentially removes quiescent power from the apparent power measurements, allowing more accurate presentation and measurement of transient power fluctuations. The lines such as 18 between each dot such as 16 and the center of the chart 20 represent the process of determining the null vector that the system adds to the reference apparent power to remove quiescent power from future measurements. FIG. 3 shows the resulting display where all three dots have moved to center 20, indicating that the quiescent power has been nulled and the apparent power appears to be zero for all three phases.

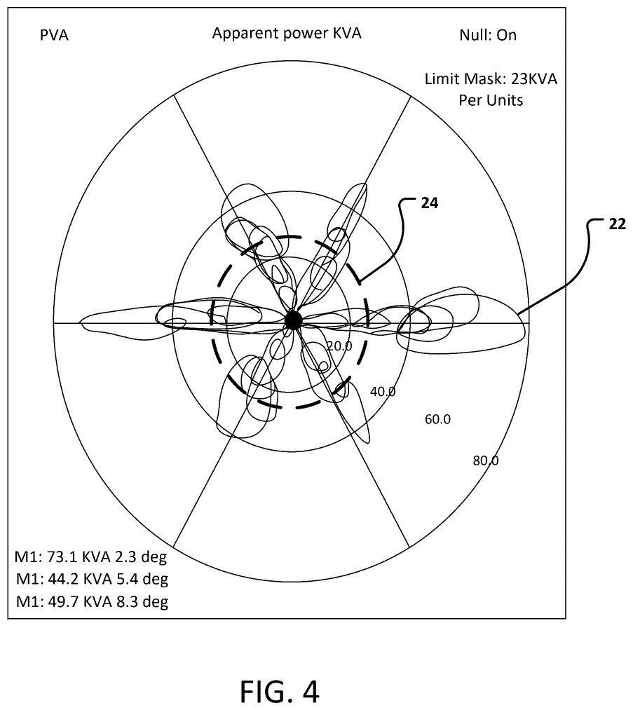

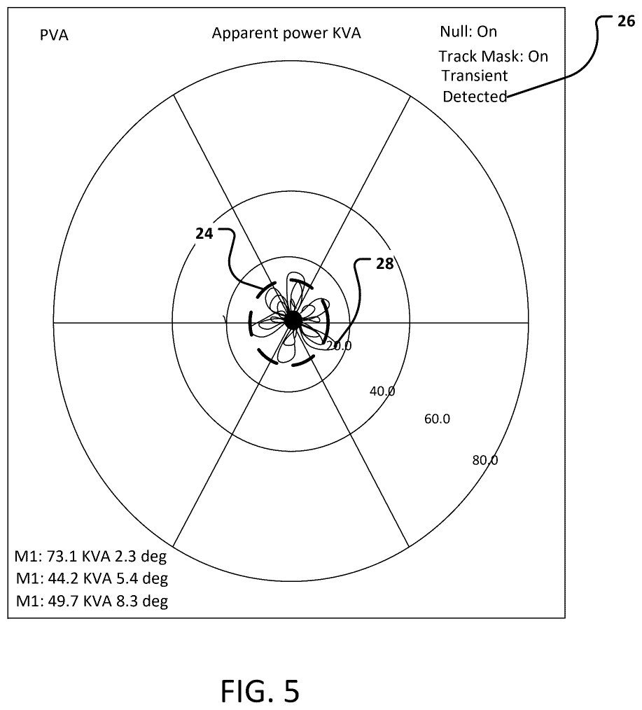

FIG. 4 shows transient apparent power fluctuations relative to the null center, with transients shown for each phase of power, such as 22. One aspect of the embodiments allows the user to set a limit mask, represented by the circle 24 shown in FIGS. 4 and 5. The limit mask sets a limit of the apparent power measurements as to how far “away” or above the null center the transients can get before causing a reaction in the PVA. In one embodiment, when the power lines are connected to a powered device, such as a motor under load, when the apparent power transient signals exceed the limit mask, such as 28, this may cause the device under test (DUT) to fail the test. In other embodiments, the limit mask may indicate a condition on the power line that requires closer monitoring or a performance of some action. The user interface presents a message such as 26, “Transient Detected.”

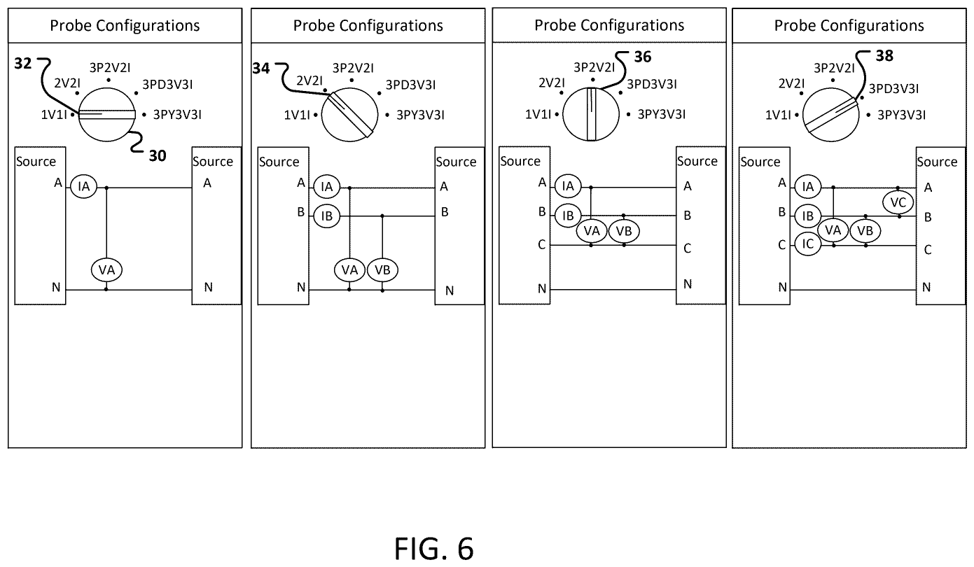

As mentioned above, the PVA may operate on three-phase power, or it may operate on one-phase power. FIG. 6 shows four different variations on the configurations of the user interface control 30 to control the probes used to send measurements of the power signal to the PVA. The far left shows the probe configuration 32 for one-phase power with one probe for voltage (1V) and one probe for current (1I), so the setting is 1V1I. Each probe will connect to one channel on the PVA. The second from the left 34 shows the setting for two voltage probes (2V) and two current probes (2I) for one-phase power, but where there are two conducting lines as in 220 V power. The second from the right 36 shows three-phase power (3P), with two voltage probes (2V) and two current probes (2I). The final panel shows the probe control set to three-phase power at 38 where they are in a “delta” configuration with three voltage probes and three current probes. The final setting, not shown as selected here, comprises a configuration for three-phase power in a “wye” configuration having three voltage and three current probes.

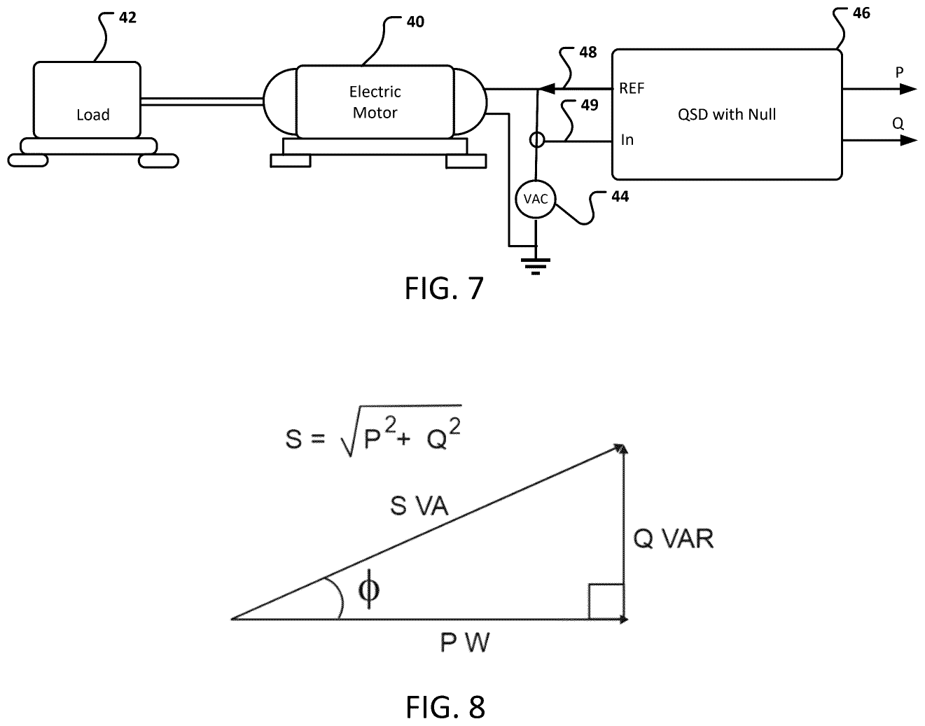

FIG. 7 shows a diagram of an electric motor 40 connected to a load 42 and connected to power 44. In this embodiment the PVA includes a quadrature synchronous detector (QSD) “with null” at 46. How the QSD of the embodiments determines the null vector to null the quiescent power will be discussed in detail further below. The QSD outputs the real power, P, and the reactive power, Q. FIG. 8 shows the relationship between P, Q, and the apparent power, S, shown on the user interfaces in FIGS. 1-5.

With this configuration, one method of testing the motor may follow this process. The user connects one or more voltage probes such as 48 and one or more current probes such as 49 to the power line. The user then selects the Null button shown previously in FIGS. 1-3 to start the null process.

The null process may occur using one of two alternatives. In one embodiment, the user connects a “golden” reference device such as a motor, meaning a device that meets all specifications and has documented responses, to the PVA. The user would then press the Null button for each phase being measured. The user interface may also include a master Null to do all three simultaneously. The null takes very little time and moves the phase traces discussed above to the center of the graphical display as shown in FIGS. 2 and 3. All further display of complex power is with respect to this reference.

As the PVA of the embodiments may operate in both one-phase and three-phase power, this discussion refers to these options as the “phase being measured,” or “each phase being measured,” where the phase being measured comprises one phase for one-phase power, or each of the three phases of three-phase power.

In another embodiment, the user sets the DUT device, such as a motor, to a reference load value, frequency, and voltage. The PVA uses these to generate the null vector and null the quiescent power. All further display of complex power is with respect to this reference. Other embodiments may use combinations, such as the golden motor in combination with the DUT.

The discussion here will refer the voltage and current signals used by the QSD to null the quiescent power as “reference voltage” and “reference current.” Once the null process has completed and the PVA monitors the power signal(s), discussion will continue to refer to the voltage and current being monitored as the reference voltage and the reference current for simplicity.

Once the null process has completed, the PVA may test different loads on the DUT, meaning it will test at various loads resulting in different voltages and frequency settings. For best implementation, the channels of the PVA connected to the voltage and current signal(s) will employ analog-to-digital converters (ADC). For the ideal implementation, all A/D samples will be stream-processed to the display. However, some test and measurement instruments upon which the PVA may be implemented may not have a high enough sample rate to support stream processing. The instrument will operate with a long enough record length so that only small gaps in the processing stream will not go to the display.

One aspect of the embodiments lies in the ability of allowing the user to set a limit mask, such as that shown previously in FIG. 5. As discussed above, the user can define a limit beyond which the PVA will flag any transient apparent power fluctuations the exceed the limit mask. The user may set a threshold using the limit mask, such as a number of times a transient in a phase exceeded the limit mask, or a length of time the transient exceeded the limit mask as a pass/fail trigger, or for levels of notifications. Returning to FIG. 5, the display posts a notification 26 that a transient has been detected. To aid in the setting and monitoring of a limit mask, the PVA may have a rotate knob. This allows the user to rotate the grid, and data to a 3-phase view, or manually adjust to optimize the data layout of each phase leg of the motor. This allows for easy drawing of masks or viewing. It also allows data from all three legs to be displayed with the correct global phase with respect to each other.

During operation of the test and analysis mode, the PVA may perform complex apparent power measurements and display readouts. Any glitches or deviation transients will be captured on the display and presented to the limit test masks. This provides an advantage for continuous monitoring and debugging of problems with a DUT.

The discussion now turns to the QSD with null shown in FIG. 7 for a one-phase power device under load, such as a motor with one-phase power 44. The QSD with Null 46 receives an input from the high-voltage probe 48 as the REF signal, and an input from the current probe 49, as the In signal. The QSD outputs the real power, P, and the reactive power, Q, used to determine the apparent power. FIG. 8 shows the relationship between the real power in Watts, the reactive power in VARs (Volt Ampere reactive), and the apparent power, S in VA (Volt Amperes).

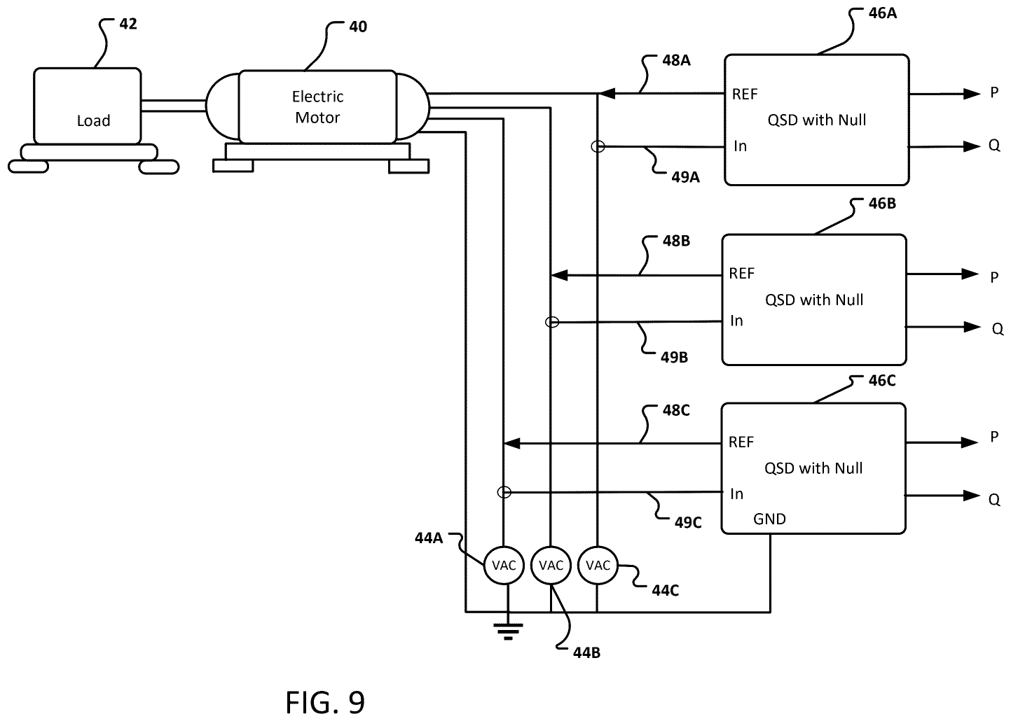

FIG. 9 shows a configuration for a three-phase power device under load. Each phase of power 44A-44C has a corresponding QSD 46A-46C. The QSD(s) measure complex power. Each QSD has a high-voltage probe, 48A-C, and current probe 49A-C.

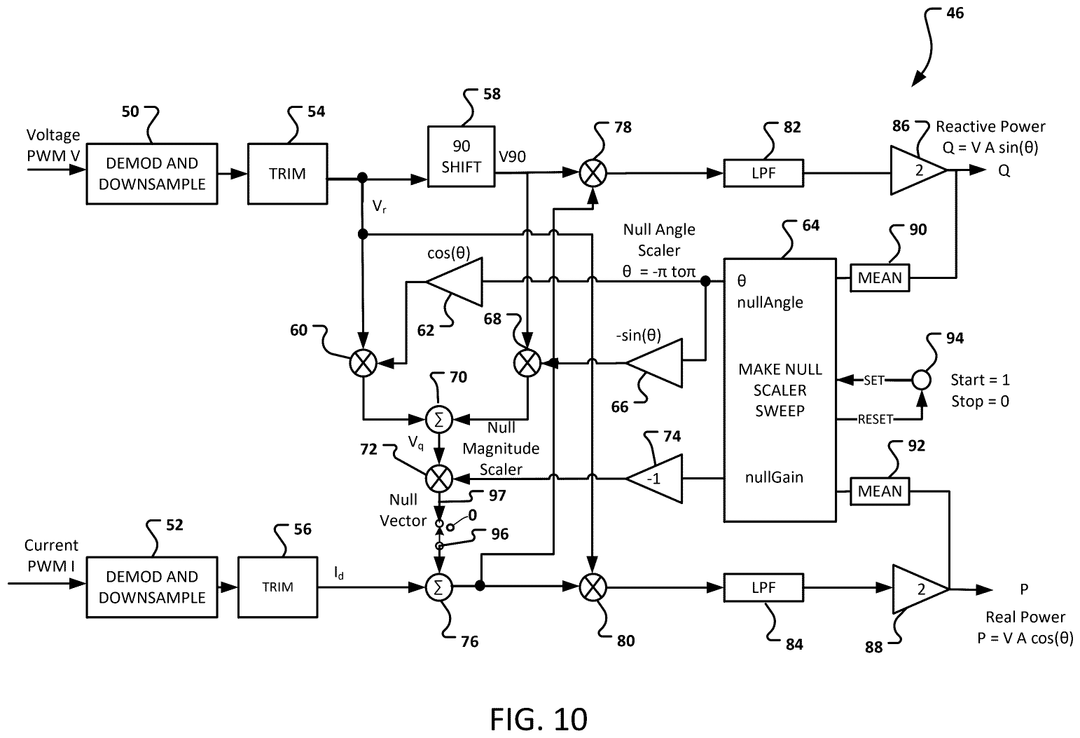

FIG. 10 shows a detailed depiction of one QSD 46. This would be replicated for each of the phases being measured by the PVA as discussed above. FIG. 10 shows the layout, and the discussion here focuses on the null process. The QSD receives the voltage signal, also referred to as the reference voltage, at the top and the current signal, also referred to as the reference current, at the bottom. The voltage signal undergoes demodulation and down sampling at 50, and the current signal undergoes demodulation and down sampling at 52. The application of the filters causes transients at the beginning and the end of acquired waveforms, so the demodulated and down sampled voltage signal is trimmed at 54, and the current signal is trimmed at 56 to remove the transients. The reference voltage signal is represented by the cosine of the reference voltage signal. The Hilbert filter 58 uses the cosine of the voltage signal and rotates, or shifts, it 90 degrees in phase. This changes the phase of the voltage signal to be shifted by 90 degrees for each frequency component at “V90,” referred to here as the shifted voltage signal. The cosine of the voltage signal, Vr, goes to a mixer 60 wherein it will be mixed with a cosine of the null angle θ from amplifier 62. The null angle θ has an initial value between −π and π. The null angle and the null gain come from the scaler sweep module 64. The sine of the null angle 66 is mixed with the shifted voltage signal at mixer 68.

The output of mixers 60 and 68 are summed at 70 to produce Vq. Vq then goes to mixer 72 and mixes with the inverse of the null gain from inverter 74 to become the Null Vector 97. The Null Vector is added to the demodulated and down sampled current signal at summing node 76. The result of that summation then mixes with the shifted voltage signal at mixer 78, and the cosine of the voltage signal at mixer 80. The outputs of the mixers 78 and 80 undergo low pass filtering at 82 and 84, respectively. The low pass filters are based upon the frequency f and are scaled by multiplying by 2 at 86 and 88 to produce Q, the reactive power, and P, the real power. The mean of Q at 90, and the mean of P at 92 are returned to the null scaler sweep block 64 and the process iterates until the values for P and Q equal zero. This results in the apparent power display being centered as shown in FIG. 3. The gain value and the phase value that cause those values to go to zero are the final Null Vector. Adding the Null Vector to the incoming voltage and current signals cancels those out to remove quiescent power. The Null Flag at 94 determines when the null process occurs. If the user presses the Null button on the user interface, the null process begins. When the null process has reached zero values for Q and P, the Null Flag resets back to 0.

The process shown in FIG. 10 is replicated for the other phases of power if needed, so the three phases of power are nulled simultaneously. The above process occurs because the user selected the Null button on the user interface, which sets the Null Flag to 1, or ON. After the process is complete, the Null Flag is reset to 0. The QSD continues to perform the null process unless turned OFF. The apparent power measurements after the null process completes do not include the quiescent power that has been removed by the null process.

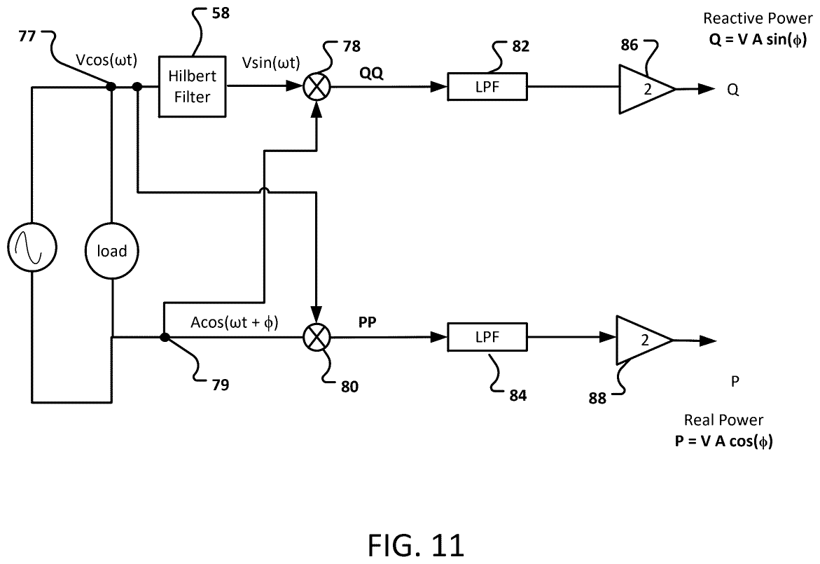

A menu option allows the user to turn off the null operation at any time in order to observe the actual total power. A switch 96 may allow control of whether or not the null process occurs. FIG. 11 shows a more focused version of the QSD for making those measurements when the null process is OFF, meaning switch 96 is open. One should note that this process occurs as in FIG. 10 but is simplified to ease understanding of the complex apparent power measurements without the null process. Similar to FIG. 10, FIG. 11 shows an incoming power signal that has a reference voltage signal component of the voltage across the load in Volts RMS (root mean squared), and the reference current in Amperes RMS. The diagram denotes the phase angle as ϕ. The term ω is the rate of change of the phase of a waveform, and equals 2πf, with f being the frequency, and t is time. The ω term has a range of between 20 and 2000.

The process takes a representation of the reference voltage signal comprising the cosine of (ωt) of the reference voltage signal V at 77 before application of the Hilbert filter at 58. The discussion here will refer to the representation as the cosine voltage function. Similarly, the cosine of (ωt+ϕ) is used as a representation of the reference current signal, A, at 79 referred to here as the cosine current function where the cosine current function is shifted in phase relative to the reference voltage. The cosine current function and the cosine voltage function are multiplied at 80 to produce PP, the real power discussed below. The cosine voltage signal is shifted 90 degrees by the Hilbert filter, resulting in a voltage sine function, V sin(ωt). The voltage sine function is multiplied with the cosine current function at 78 to produce signal QQ, the reactive power also discussed below. These two signals undergo low-pass filtering, and then are scaled by 2, as discussed with regard to FIG. 10. The scale factor of 2 is explained below to produce the reactive power as V A sin(ϕ) and real power as V A cos(ϕ). These are then used to find the apparent power of the power line, which is used for display.

The determination of the signals PP and QQ are as follows:

QQ=A·cos(ωt+ϕ)·V·sin(ωt) PP=A·cos(ωt+ϕ)·V·cos(ωt)

Rearranging the terms and applying the trigonometry identity in which cos(a+b)=cos(a)cos(b)−sin(a)sin(b) to both QQ and PP results in:

QQ=VA·cos(ωt+ϕ)cos(ϕ)sin(ωt)−VA·sin(ωt)sin(ϕ)sin(ωt)

PP=VA·cos(ωt)cos(ϕt)cos(ϕ)−VA·sin(ϕ)sin(ωt)cos(ωt)

Applying the trig identities in which cos(a)sin(a)=sin(2a)/2, sin(a)sin(a)=cos(2a)/2−½ and cos(a)cos(a)=cos(2a)/2+½ and then rearranging the terms results in:

$$QQ = VA / 2 \cdot sin ( 2 ω t ) cos ( ϕ ) + VA / 2 \cdot sin ( ϕ ) - VA / 2 \cdot cos ( 2 ω t ) sin ( ϕ ) \\ PP = VA / 2 \cdot cos ( 2 ω t ) cos ( ϕ ) + VA / 2 \cdot cos ( ϕ ) - VA / 2 \cdot sin ( 2 ω t ) sin ( ϕ ) .$$

The low pass filters are then applied to QQ and PP to remove the higher frequency terms, leaving QQ=VA/2·sin(ϕ) and PP=VA/2·cos(ϕ). Applying the scale factor of 2 shown in the figures results in Q=VAsin(ϕ), and P=VAcos (ϕ). These power measurements are then used to find the apparent power, S, of the power line at that point in time.

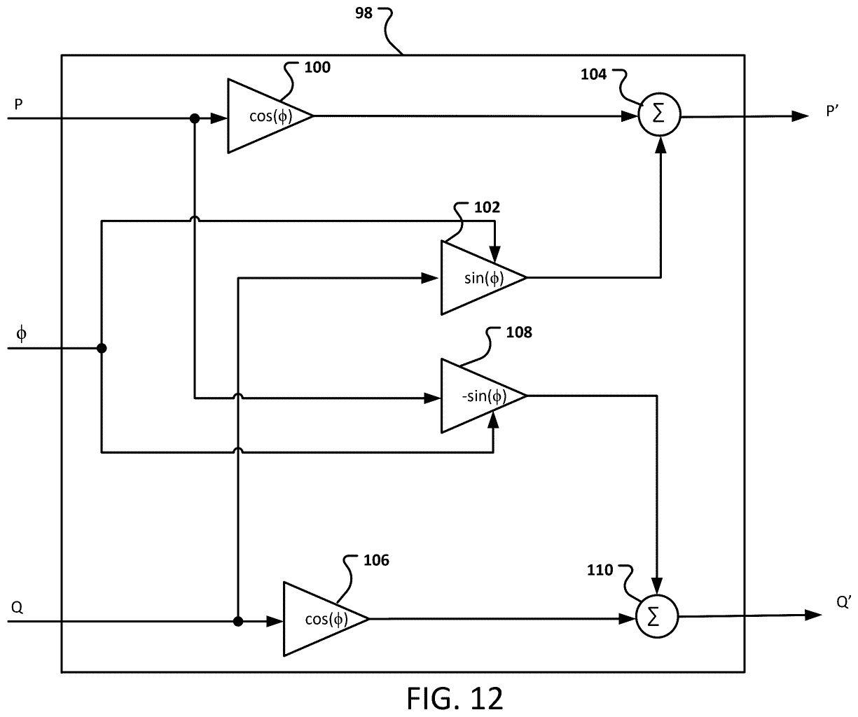

FIG. 12 shows an embodiment of a rotation block 98. The rotation block is independent of rotating the complex output of the QSD in the normalized XY plane where P is defined for an X-axis position, and Q is defined for Y-axis position. The normal P and Q output of a QSD on each of the three legs of a 3-phase motor would appear on a single polar grid map. Each individual leg would have the standard rotation of zero of a polar grid view. This would lose the global phase difference between each leg of the motor. In FIG. 12, the cosine of the phase of the power signals P and Q is multiplied with the P signal at 100 and then summed with the sine of the phase angle 102 at summing node 104. Similarly, the cosine of the phase angle is multiplied with the Q signal at 106 and then summed with the sine of the phase angle 108 at summing node 110.

In one embodiment, the first phase of the motor could be displayed on the display with zero degrees of rotation. The second phase could be displayed with 120 degrees of rotation and the third phase with 240 degrees of rotation. See the right-hand image in FIG. 1 for an example, where each dot is 120 degrees offset from each other. In an alternative embodiment, an additional global phase measurement between the three voltages could be made and used to set the rotation block phase angles. Another useful display embodiment may be to display all three phases overlaid with zero degrees of rotation. All three motor legs' power could be directly compared visually in the overlay view. In addition, this would potentially allow for creating only one limit mask for all three legs. When creating a limit mask, it may be useful to rotate the polar grid to an angle that makes it easier to draw the limit mask. It may be optimal that once a limit mask is drawn, it would rotate with the display.

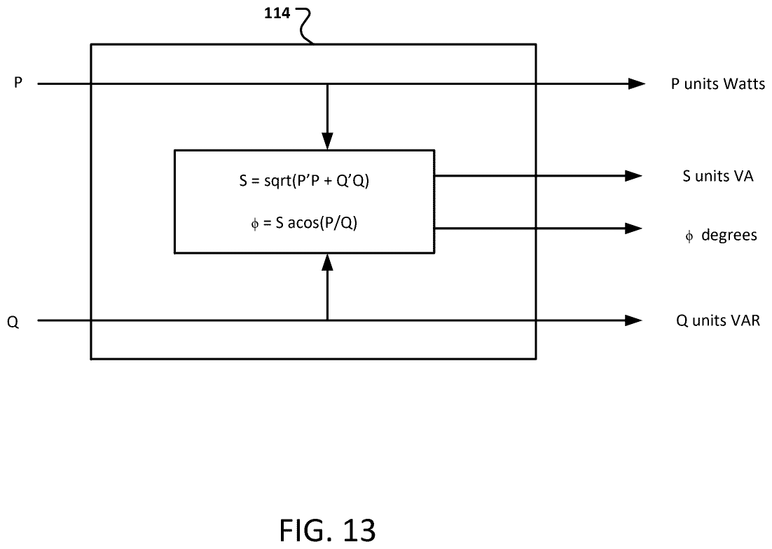

FIG. 13 is an embodiment of an apparent power block 114 to compute the apparent power and the power factor angle ϕ. The purpose of apparent power block 114 is to output P in units of Watts, Q in unit of VAr, S in units of VA, and ϕ in degrees.

A possible advantage of doing this from the output of the QSD, rather than direct measurements on the voltage and current waveforms, is the improved noise reduction and resolution of the measurement resulting from the averaging effects of the QSD. A second advantage may be that the measurement tracks in time position in the acquired data stream, as it changes based on load, frequency, and voltage. The measurements can be tagged with time, and the markers on the XY display with the polar grid can be tracked together with cursors on the YT view of the three input voltage waveforms and the three input current waveforms.

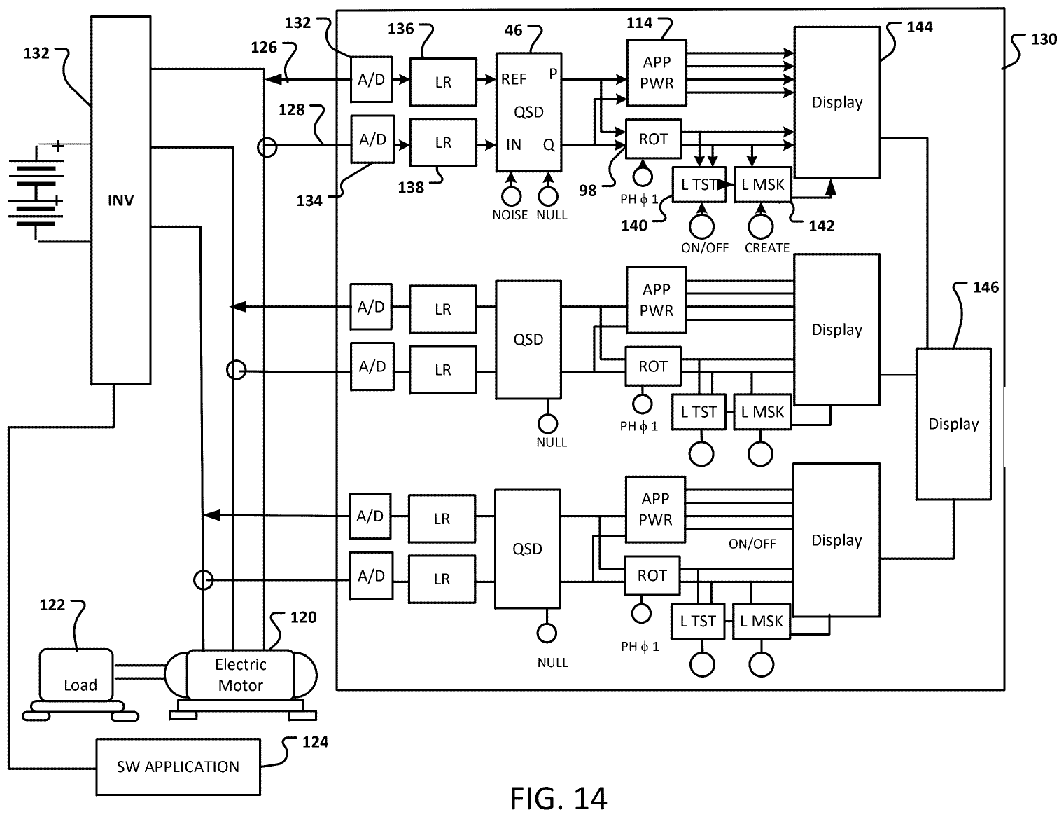

FIG. 14 shows an embodiment of a block diagram of a PVA configured with a DUT motor 120 after the system was nulled with a golden reference motor. Alternatively, using the DUT motor, the system may be nulled with a reference frequency, voltage, and load setting. In this embodiment, the only hardware required for this architecture are three voltage probes, three current probes, and an instrument such as an oscilloscope or a digitizer 130. Also, the user provides the variable load 122 and DUT motor 120. An additional aspect of the present invention is software application 124 that may be run on instrument 130, such as an oscilloscope or digitizer system. One or more processors on the instrument 130 may be configured to execute code that causes the one or more processors to run the software application 124. The QSD discussed above may be implemented in a processor or in logic circuitry.

The architecture comprises three main QSD processing paths, one for each leg of the three-phase power device. Note that single phase motors may be analyzed by only enabling one leg of the signal processing paths. The discussion here uses the first QSD path for discussion with the understanding that the discussion applies to each leg. The current probe 128 connects to one channel of the instrument, and the high voltage probe 126 connects to another channel of the instrument. Each channel has one or more analog-to-digital converters (ADC), such as 132 and 134.

As mentioned above, depending upon the capability of the instrument, the samples from the ADC may be continuously streamed or used to form a long record (LR) such as 136 and 138. While these are named LR here, they may also be continuously streamed. These represent a continuous sample stream going into the signal processing path with all output samples going to the infinite persistence display. Persistence may also be set to decay. This continuous stream, sometimes called roll mode block, is optional in the event the instrument 130 does not have a high enough streaming sample rate to support the highest frequencies to be sampled in the motor. This would include distortion harmonics. If the roll mode sample rate is not high enough, then this roll mode block is not used, and relatively long record length waveform would be used so that the dead time between acquisitions is relatively small so that a large percentage of all samples make it to the display.

The QSD 46, previously discussed, operates on the voltage and current signals in sample form. Depending upon the setting of the null flag, the QSD may either find the nulled quiescent power, or make complex power measurements. The rotation block 98 and apparent power block 114 are applied to the signals. The user then turns on or off the limit test at 140 and may draw a limit mask as selected at 142. All the results are then displayed, either as a single display 144, or as a multilayered display showing data from all three legs at 146.

In operation, the user would connect the probes to the instrument and the power device, such as a motor. The user would then set the instrument acquisition to capture all six channels with appropriate gains settings. The user would then launch the PVA software application and assign signals to the instrument channels. First, the instrument must perform the null process. The user would set the desired frequency, reference load, and voltage. If the null process uses a golden reference motor, once null is achieved, the user will need to switch the probes to the DUT power device. The null feature may also be used for cases such as monitoring three phase power on the power grid. The null feature may be used to null out the nominal quiescent power so that the display on the PVA polar grid will show only the deviations away from the nominal power. This would be useful for capturing power transients such as lightning strikes, or load switching variations, or other types of transients that might occur. At this point, the user would observe the complex power data continuously as the motor conditions vary, the measured power vectors P, Q, and S, and the transient behavior with real-time load changes. This allows the user to set up masks for pass/fail testing, or other triggered events.

The user interface may include play/pause/stop playback control with fast forward, the entire time record can be visually analyzed in a short period, and all samples over the entire interval can be viewed in one view on the display giving insight not seen with previous power analyzers.

One should note that the embodiments include the sum of multiple elements. The combination of these elements creates a new and highly useful PVA. Some of these architectural elements for embodiments of the present invention may include an inverter 132, as shown in FIG. 14. This drives the power device as part of the DUT or laboratory setup for testing. It is configured to deliver three-phase pulse width modulated sine wave voltage and current. The frequency may vary over a range, and the voltage may vary to realize optimal operation of the electric motor for torque and power.

As part of the testing of the power device, a user will employ a variable load. The customer test automation software 124 would control the load setting. The power device is coupled to the shaft of the variable load. The customer provides the customer test automation software for testing of power devices and controlling the PVA settings during the needed procedures.

In this manner, the embodiments provide a PVA for analysis of high-power electric devices, such as one-phase and three-phase motors. The PVA provides a real-time continuous complex power plot of all three motor phases. It can provide a plot representing the apparent power, the reactive power, and the real power for each motor phase. The PVA also has a unique null feature analogous to calibrating a 1-port VNA, that calibrates with respect to a reference power setting. The reference power setting may come from a reference motor, or the DUT set to a reference voltage, load, and frequency, then doing a null calibration. Once nulled, the PVA can continuously monitor and capture all samples over time onto an infinite persist display. It can create a power map over the entire range of load, frequency, and voltage. It also captures glitches and other buggy behaviors. Limit testing can flag glitches and transients. Using an instrument platform for the PVA means that other measurement waveform analysis tools of the instrument may also be used in the testing process of the motor, providing additional benefit to the user.

Aspects of the disclosure may operate on a particularly created hardware, on firmware, digital signal processors, or on a specially programmed general purpose computer including a processor operating according to programmed instructions. The terms controller or processor as used herein are intended to include microprocessors, microcomputers, Application Specific Integrated Circuits (ASICs), and dedicated hardware controllers. One or more aspects of the disclosure may be embodied in computer-usable data and computer-executable instructions, such as in one or more program modules, executed by one or more computers (including monitoring modules), or other devices. Generally, program modules include routines, programs, objects, components, data structures, etc. that perform particular tasks or implement particular abstract data types when executed by a processor in a computer or other device. The computer executable instructions may be stored on a non-transitory computer readable medium such as a hard disk, optical disk, removable storage media, solid state memory, Random Access Memory (RAM), etc. As will be appreciated by one of skill in the art, the functionality of the program modules may be combined or distributed as desired in various aspects. In addition, the functionality may be embodied in whole or in part in firmware or hardware equivalents such as integrated circuits, FPGA, and the like. Particular data structures may be used to more effectively implement one or more aspects of the disclosure, and such data structures are contemplated within the scope of computer executable instructions and computer-usable data described herein.

The disclosed aspects may be implemented, in some cases, in hardware, firmware, software, or any combination thereof. The disclosed aspects may also be implemented as instructions carried by or stored on one or more or non-transitory computer-readable media, which may be read and executed by one or more processors. Such instructions may be referred to as a computer program product. Computer-readable media, as discussed herein, means any media that can be accessed by a computing device. By way of example, and not limitation, computer-readable media may comprise computer storage media and communication media.

Computer storage media means any medium that can be used to store computer-readable information. By way of example, and not limitation, computer storage media may include RAM, ROM, Electrically Erasable Programmable Read-Only Memory (EEPROM), flash memory or other memory technology, Compact Disc Read Only Memory (CD-ROM), Digital Video Disc (DVD), or other optical disk storage, magnetic cassettes, magnetic tape, magnetic disk storage or other magnetic storage devices, and any other volatile or nonvolatile, removable or non-removable media implemented in any technology. Computer storage media excludes signals per se and transitory forms of signal transmission.

Communication media means any media that can be used for the communication of computer-readable information. By way of example, and not limitation, communication media may include coaxial cables, fiber-optic cables, air, or any other media suitable for the communication of electrical, optical, Radio Frequency (RF), infrared, acoustic or other types of signals.

### EXAMPLES

Illustrative examples of the disclosed technologies are provided below. An embodiment of the technologies may include one or more, and any combination of, the examples described below.

Example 1 is a power vector analyzer to analyze power from a device under test (DUT), comprising: one or more channels to measure a reference voltage signal from a power line connected to the DUT; one or more channels to measure a reference current signal from the power line; a user interface comprising a display and one or more controls; and a quadrature synchronous detector (QSD) for each phase of apparent power being measured, the QSD configured to use a reference voltage signal from the one or more channels and a reference current signal from the one or more channels to determine the apparent power for each phase of power being measured by the DUT and display the apparent power for each phase on the display.

Example 2 is the power vector analyzer of Example 1, further comprising: one or more processors configured to execute code that causes the one or more processors to: receive a signal through the one or more controls on the user interface from a user indicating the user wants to start a null process; send a signal to the QSD to generate a null vector; apply the null vector to the reference voltage and the reference current to remove quiescent power; and display apparent power signals for test voltages and test currents relative to the nulled quiescent power for each phase of power.

Example 3 is the power vector analyzer of Example 2, wherein the one or more processors are further configured to display a reference apparent power signal for each phase being measured as the QSD for each phase generates the null vector as the reference apparent power signal moves to zero.

Example 4 is the power vector analyzer of Example 3, wherein the code that causes the one or more processors to display test power signals comprises code to display reference power signals for each phase overlaid onto one display.

Example 5 is the power vector analyzer of any of Examples 2 through 4, wherein the reference voltage signal and the reference current signal for the null process are generated by the DUT being operated at a reference load value, a reference frequency, and a reference voltage.

Example 6 is the power vector analyzer of any of Examples 2 through 5, wherein the reference voltage signal and the reference current signals for the null process are generated by a reference motor used to produce the nulled quiescent power.

Example 7 is the power vector analyzer of any of Examples 1 through 6, wherein three phases of power are being measured, and the QSD for each phase of power comprises three QSDs, and the apparent power display displays apparent power for each of three phases of power.

Example 8 is the power vector analyzer of any of Examples 1 through 7, wherein the reference voltage signal from the one or more channels and the reference current signal from the one or more channels are the quiescent operating power on DUT power lines.

Example 9 is the power vector analyzer of any of Examples 1 through 8, wherein the one or more controls comprises a control to allow the user to move the apparent power signal for each phase being measured on the display as desired by the user.

Example 10 is the power vector analyzer of any of Examples 1 through 9, wherein the one or more controls comprise a control to allow the user to define a limit mask on the display, the limit mask indicating a region of apparent power signals that is within a passing limit.

Example 11 is the power vector analyzer of Example 10, wherein the one or more processors are further configured to pass the DUT when the apparent power measurements do not exceed the limit mask, and to fail the DUT when the apparent power measurements exceed the limit mask.

Example 12 is the power vector analyzer of any of Examples 1 through 11, wherein the QSD for each phase of power uses the reference voltage signal and reference current signal to produce the apparent power by: multiplying the reference voltage signal represented by a cosine voltage function with the reference current signal represented by a cosine current function, the cosine current function having a phase shift with respect to the reference voltage to produce a result, and filtering the result to obtain a true power value; shifting the cosine voltage function by 90 degrees to produce a shifted voltage function as a sine voltage function; multiplying the sine voltage function with the cosine current function and filtering the result to produce a reactive power signal; and using the reactive power signal and the real power signal to produce the apparent power.

Example 13 is a method of measuring one or more power signals, comprising: measuring a reference voltage signal from a power line connected to a device under test; measuring a reference current signal from the power line; using a quadrature synchronous detector (QSD) for each phase of power being measured to take the reference voltage signal and the reference current signal to produce an apparent power for each phase of power being measured by the DUT; and displaying apparent power relative to a nulled quiescent power for each phase of apparent power being measured.

Example 14 is the method of Example 13, further comprising: receiving a signal through the one or more controls on the user interface from a user indicating the user wants to start a null process; sending a signal to the QSD to generate a null vector; applying the null vector to the reference voltage signal and the reference current signal to produce the nulled power quiescent; and displaying apparent power signals for relative to the nulled power quiescent for each phase of power.

Example 15 is the method of Example 14, further comprising displaying a reference apparent power for each phase being measured as the QSD generates the null vector and the reference voltage and reference current signals move to zero.

Example 16 is the method of Example 14, wherein the reference voltage signal and the reference current signal are generated by the DUT being operated at a reference load value, a reference frequency, and a reference voltage.

Example 17 is the method of Example 14, wherein the reference voltage signal and the reference current signals are generated by a reference DUT used produce the nulled quiescent power.

Example 18 is the method of any of Examples 13 through 17, wherein one or either three phases of power or one phase of power is being measured.

Example 19 is the method of Example 17, wherein three phases of apparent power are being measured and displaying apparent power signals comprises displaying apparent power signals for each phase overlaid onto one display.

Example 20 is the method of any of Examples 13 through 19, further comprising allowing the user to move the apparent power signal for each phase being measured on the display as desired by the user.

Example 21 is the method of any of Examples 13 through 20, further comprising allowing the user to define a limit mask on the display, the limit mask indicating a region of apparent power that are within a passing limit.

Example 22 is the method of any of Examples 13 through 21, wherein the QSD for each phase of power uses the reference voltage signal and reference current signal to generate the apparent power by: multiplying the reference voltage signal represented by a cosine voltage function with the reference current signal represented by a cosine current function, the cosine current function having a phase shift with respect to the reference voltage to produce a result, and filtering the result to obtain a true power value; shifting the cosine voltage function by 90 degrees to produce a shifted voltage function as a sine voltage function; multiplying the sine voltage function with the cosine current function and filtering the result to produce a reactive power signal; and using the reactive power signal and the real power signal to produce the apparent power.

Additionally, this written description makes reference to particular features. It is to be understood that the disclosure in this specification includes all possible combinations of those particular features. Where a particular feature is disclosed in the context of a particular aspect or example, that feature can also be used, to the extent possible, in the context of other aspects and examples.

Also, when reference is made in this application to a method having two or more defined steps or operations, the defined steps or operations can be carried out in any order or simultaneously, unless the context excludes those possibilities.

All features disclosed in the specification, including the claims, abstract, and drawings, and all the steps in any method or process disclosed, may be combined in any combination, except combinations where at least some of such features and/or steps are mutually exclusive. Each feature disclosed in the specification, including the claims, abstract, and drawings, can be replaced by alternative features serving the same, equivalent, or similar purpose, unless expressly stated otherwise.

Although specific examples of the invention have been illustrated and described for purposes of illustration, it will be understood that various modifications may be made without departing from the spirit and scope of the invention. Accordingly, the invention should not be limited except as by the appended claims.

1. A power vector analyzer to analyze power from a device under test (DUT), comprising:
one or more channels to measure a reference voltage signal from a power line connected to the DUT;
one or more channels to measure a reference current signal from the power line;
a user interface comprising a display and one or more controls; and
a quadrature synchronous detector (QSD) for each phase of apparent power being measured, the QSD configured to use a reference voltage signal from the one or more channels and a reference current signal from the one or more channels to determine the apparent power for each phase of power being measured by the DUT and display the apparent power for each phase on the display.

2. The power vector analyzer as claimed in claim 1, further comprising:
one or more processors configured to execute code that causes the one or more processors to:
receive a signal through the one or more controls on the user interface from a user indicating the user wants to start a null process;
send a signal to the QSD to generate a null vector;
apply the null vector to the reference voltage and the reference current to remove quiescent power; and
display apparent power signals for test voltages and test currents relative to the nulled quiescent power for each phase of power.

3. The power vector analyzer as claimed in claim 2, wherein the one or more processors are further configured to display a reference apparent power signal for each phase being measured as the QSD for each phase generates the null vector as the reference apparent power signal moves to zero.

4. The power vector analyzer as claimed in claim 3, wherein the code that causes the one or more processors to display test power signals comprises code to display reference power signals for each phase overlaid onto one display.

5. The power vector analyzer as claimed in claim 2, wherein the reference voltage signal and the reference current signal for the null process are generated by the DUT being operated at a reference load value, a reference frequency, and a reference voltage.

6. The power vector analyzer as claimed in claim 2, wherein the reference voltage signal and the reference current signals for the null process are generated by a reference motor used to produce the nulled quiescent power.

7. The power vector analyzer as claimed in claim 1, wherein three phases of power are being measured, and the QSD for each phase of power comprises three QSDs, and the apparent power display displays apparent power for each of three phases of power.

8. The power vector analyzer as claimed in claim 1, wherein the reference voltage signal from the one or more channels and the reference current signal from the one or more channels are the quiescent operating power on DUT power lines.

9. The power vector analyzer as claimed in claim 1, wherein the one or more controls comprises a control to allow the user to move the apparent power signal for each phase being measured on the display as desired by the user.

10. The power vector analyzer as claimed in claim 1, wherein the one or more controls comprise a control to allow the user to define a limit mask on the display, the limit mask indicating a region of apparent power signals that is within a passing limit.

11. The power vector analyzer as claimed in claim 10, wherein the one or more processors are further configured to pass the DUT when the apparent power measurements do not exceed the limit mask, and to fail the DUT when the apparent power measurements exceed the limit mask.

12. The power vector analyzer as claimed in claim 1, wherein the QSD for each phase of power uses the reference voltage signal and reference current signal to produce the apparent power by:
multiplying the reference voltage signal represented by a cosine voltage function with the reference current signal represented by a cosine current function, the cosine current function having a phase shift with respect to the reference voltage to produce a result, and filtering the result to obtain a true power value;
shifting the cosine voltage function by 90 degrees to produce a shifted voltage function as a sine voltage function;
multiplying the sine voltage function with the cosine current function and filtering the result to produce a reactive power signal; and
using the reactive power signal and the real power signal to produce the apparent power.

13. A method of measuring one or more power signals, comprising:
measuring a reference voltage signal from a power line connected to a device under test;
measuring a reference current signal from the power line;
using a quadrature synchronous detector (QSD) for each phase of power being measured to take the reference voltage signal and the reference current signal to produce an apparent power for each phase of power being measured by the DUT; and
displaying apparent power relative to a nulled quiescent power for each phase of apparent power being measured.

14. The method as claimed in claim 13, further comprising:
receiving a signal through the one or more controls on the user interface from a user indicating the user wants to start a null process;
sending a signal to the QSD to generate a null vector;
applying the null vector to the reference voltage signal and the reference current signal to produce the nulled power quiescent; and
displaying apparent power signals for relative to the nulled power quiescent for each phase of power.

15. The method as claimed in claim 14, further comprising displaying a reference apparent power for each phase being measured as the QSD generates the null vector and the reference voltage and reference current signals move to zero.

16. The method as claimed in claim 14, wherein the reference voltage signal and the reference current signal are generated by the DUT being operated at a reference load value, a reference frequency, and a reference voltage.

17. The method as claimed in claim 14, wherein the reference voltage signal and the reference current signals are generated by a reference DUT used produce the nulled quiescent power.

18. The method as claimed in claim 13, wherein one or either three phases of power or one phase of power is being measured.

19. The method as claimed in claim 17, wherein three phases of apparent power are being measured and displaying apparent power signals comprises displaying apparent power signals for each phase overlaid onto one display.

20. The method as claimed in claim 13, further comprising allowing the user to move the apparent power signal for each phase being measured on the display as desired by the user.

21. The method as claimed in claim 13, further comprising allowing the user to define a limit mask on the display, the limit mask indicating a region of apparent power that are within a passing limit.

22. The method as claimed in claim 13, wherein the QSD for each phase of power uses the reference voltage signal and reference current signal to generate the apparent power by:
multiplying the reference voltage signal represented by a cosine voltage function with the reference current signal represented by a cosine current function, the cosine current function having a phase shift with respect to the reference voltage to produce a result, and filtering the result to obtain a true power value;
shifting the cosine voltage function by 90 degrees to produce a shifted voltage function as a sine voltage function;
multiplying the sine voltage function with the cosine current function and filtering the result to produce a reactive power signal; and
using the reactive power signal and the real power signal to produce the apparent power.
